(19) United States
(12) Patent Application Publication
(10) Pub. No.: US 2024/0128153 A1
(43) Pub. Date: Apr. 18, 2024

(54) SEMICONDUCTOR POWER DEVICE AND SEMICONDUCTOR MODULE

(71) Applicant: Ganstronic INC., Tainan City (TW)

(72) Inventor: Cheng-Chuan CHEN, Tainan City (TW)

(21) Appl. No.: 18/377,807

(22) Filed: Oct. 8, 2023

(30) Foreign Application Priority Data
Oct. 17, 2022 (TW) 111139193

(51) Int. Cl. H01L 23/373; H01L 23/00; H01L 23/31

(52) U.S. Cl. CPC H01L 23/3735; H01L 23/3121; H01L 24/06; H01L 24/13; H01L 24/16; H01L 2224/06519; H01L 2224/13109; H01L 2224/13111; H01L 2224/13113; H01L 2224/13139; H01L 2224/13144; H01L 2224/13147; H01L 2224/16227

(57) ABSTRACT

A semiconductor power device includes a ceramic-metal composite circuit substrate, a flip chip and a metal thermal-conducting layer. The ceramic-metal composite circuit substrate includes first electric-conducting metal pads and a first thermal-conducting metal pad. The first thermal-conducting metal pad is not electrically connected to the first electric-conducting metal pads. The flip chip includes electric-conducting pads and a floating thermal-conducting metal pad. The electric-conducting pads are electrically connected to the first electric-conducting metal pads. The floating thermal-conducting metal pad is not electrically connected to the electric-conducting pads. The metal thermal-conducting layer is disposed on the flip chip.

### RELATED APPLICATIONS

This application claims priority to Taiwan Application Serial Number 111139193, filed Oct. 17, 2022, which is herein incorporated by reference.

### BACKGROUND

### Technical Field

The present disclosure relates to a semiconductor power device. More particularly, the present disclosure relates to a semiconductor power device with double-sided cooling ability.

### Description of Related Art

In semiconductor materials, the band gap of material is one of the important properties. Semiconductor materials with relatively large band gaps can withstand higher voltage and higher current, and energy conversion efficiency thereof is also better. Therefore, high-power chips made of wide band gap (WBG) materials, such as gallium nitride (GaN) or silicon carbide (SiC), are developed by the industry. The high-power chips are applied for products with high-voltage, high-current, and high-wattage, such as fast charging devices for electric vehicles, automotive inverters and on board chargers, or high-voltage power systems.

However, resin materials, such as epoxy resin or BT resin (bismaleimide triazine resin), are still main materials for packaging in the industry. Resin materials are inevitably used as the main part of the package in the aforementioned packaging methods. Because the high temperature generated during the operation of high-power chips cannot be transferred from the resin materials to outside effectively, it is difficult to successfully use existing high-power components for the aforementioned products with high-voltage, high-current, and high-wattage, especially to the products with the operating power over 100 watts in one single chip. In this regard, how to improve the heat dissipating efficiency of high-power components, so as to avoid the effects or damages to the high-power components caused by high-temperature, is still a problem to be solved.

### SUMMARY

According to the present disclosure, a semiconductor power device includes a ceramic-metal composite circuit substrate, a flip chip and a metal thermal-conducting layer. The ceramic-metal composite circuit substrate includes a ceramic insulating layer, a plurality of first electric-conducting metal pads and at least one first thermal-conducting metal pad. The ceramic insulating layer has a first side and a second side opposite to the first side. The plurality of first electric-conducting metal pads are disposed on the first side of the ceramic insulating layer. The at least one first thermal-conducting metal pad is disposed on the first side of the ceramic insulating layer, and not electrically connected to each of the plurality of first electric-conducting metal pads. The flip chip is disposed on the ceramic-metal composite circuit substrate, and arranged at the first side. The flip chip includes a substrate, a semiconductor structural layer, a plurality of electric-conducting pads and at least one floating thermal-conducting metal pad. The semiconductor structural layer is disposed on the substrate. The plurality of electric-conducting pads are disposed on the semiconductor structural layer, and electrically connected to the semiconductor structural layer and the plurality of first electric-conducting metal pads. The semiconductor structural layer is arranged between the substrate and the plurality of electric-conducting pads. The at least one floating thermal-conducting metal pad is disposed on the semiconductor structural layer, and connected to the at least one first thermal-conducting metal pad. The semiconductor structural layer is arranged between the substrate and the at least one floating thermal-conducting metal pad, and the at least one floating thermal-conducting metal pad is not electrically connected to the plurality of electric-conducting pads and the semiconductor structural layer. The metal thermal-conducting layer is disposed on the substrate.

According to the present disclosure, a semiconductor module includes a semiconductor power device and a driving circuit substrate. The semiconductor power device includes a ceramic-metal composite circuit substrate, a plurality of semiconductor devices and a metal thermal-conducting layer. The ceramic-metal composite circuit substrate includes a ceramic insulating layer, a plurality of first electric-conducting metal pads, at least one first thermal-conducting metal pad, at least one second thermal-conducting metal pad and a plurality of metal leads. The ceramic insulating layer has a first side and a second side opposite to the first side. The plurality of first electric-conducting metal pads are disposed on the first side of the ceramic insulating layer. The at least one first thermal-conducting metal pad is disposed on the first side of the ceramic insulating layer, and not electrically connected to each of the plurality of first electric-conducting metal pads. The at least one second thermal-conducting metal pad is disposed on the second side of the ceramic insulating layer. The plurality of metal leads are disposed on the first side of the ceramic insulating layer, and the plurality of metal leads are respectively electrically connected to the plurality of first electric-conducting metal pads. The plurality of semiconductor devices include at least one flip chip. The at least one flip chip is disposed on the ceramic-metal composite circuit substrate, and arranged at the first side. The at least one flip chip includes a substrate, a semiconductor structural layer, a plurality of electric-conducting pads and at least one floating thermal-conducting metal pad. The semiconductor structural layer is disposed on the substrate. The plurality of electric-conducting pads are disposed on the semiconductor structural layer, and electrically connected to the semiconductor structural layer and the plurality of first electric-conducting metal pads. The semiconductor structural layer is arranged between the substrate and the plurality of electric-conducting pads. The at least one floating thermal-conducting metal pad is disposed on the semiconductor structural layer, and connected to the at least one first thermal-conducting metal pad. The semiconductor structural layer is arranged between the substrate and the at least one floating thermal-conducting metal pad, and the at least one floating thermal-conducting metal pad is not electrically connected to the plurality of electric-conducting pads and the semiconductor structural layer. The metal thermal-conducting layer is disposed on the substrate. The driving circuit substrate is electrically connected to the plurality of metal leads, the plurality of first electric-conducting metal pads or the plurality of electric-conducting pads.

### BRIEF DESCRIPTION OF THE DRAWINGS

The present disclosure can be more fully understood by reading the following detailed description of the embodiment, with reference made to the accompanying drawings as follows:

FIG. 1A is a cross-sectional schematic view of the semiconductor power device according to the 1st embodiment of the present disclosure.

FIG. 1B is a cross-sectional schematic view of the semiconductor power device according to the 2nd embodiment of the present disclosure.

FIG. 2A is a cross-sectional schematic view of the semiconductor power device according to the 3rd embodiment of the present disclosure.

FIG. 2B is a top schematic view of the semiconductor power device of FIG. 2A.

FIG. 3A is a cross-sectional schematic view of the ceramic-metal composite circuit substrate according to the 3rd embodiment of the present disclosure.

FIG. 3B is a top schematic view of the ceramic-metal composite circuit substrate of FIG. 3A.

FIG. 3C is a bottom schematic view of the ceramic-metal composite circuit substrate of FIG. 3A.

FIG. 4A is a cross-sectional schematic view of the semiconductor power device according to the 4th embodiment of the present disclosure.

FIG. 4B is a top schematic view of the semiconductor power device of FIG. 4A.

FIG. 5A is a cross-sectional schematic view of the ceramic-metal composite circuit substrate according to the 4th embodiment of the present disclosure.

FIG. 5B is a top schematic view of the ceramic-metal composite circuit substrate of FIG. 5A.

FIG. 6A is a cross-sectional schematic view of the semiconductor power device according to the 5th embodiment of the present disclosure.

FIG. 6B is a top schematic view of the semiconductor power device of FIG. 6A.

FIG. 7A is a cross-sectional schematic view of the ceramic-metal composite circuit substrate according to the 5th embodiment of the present disclosure.

FIG. 7B is a top schematic view of the ceramic-metal composite circuit substrate of FIG. 7A.

FIG. 7C is a bottom schematic view of the ceramic-metal composite circuit substrate of FIG. 7A.

FIG. 8A is a cross-sectional schematic view of the semiconductor power device according to the 6th embodiment of the present disclosure.

FIG. 8B is a top schematic view of the semiconductor power device of FIG. 8A.

FIG. 9 is a cross-sectional schematic view of the semiconductor power device according to the 7th embodiment of the present disclosure.

FIG. 10 is a cross-sectional schematic view of the semiconductor power device according to the 8th embodiment of the present disclosure.

FIG. 11 is a cross-sectional schematic view of the semiconductor power device according to the 9th embodiment of the present disclosure.

FIG. 12 is a cross-sectional schematic view of the semiconductor module according to the 10th embodiment of the present disclosure.

FIG. 13 is a cross-sectional schematic view of the semiconductor module according to the 11th embodiment of the present disclosure.

### DETAILED DESCRIPTION

The present disclosure will be further exemplified by the following specific embodiments. However, the embodiments can be applied to various inventive concepts and can be embodied in various specific ranges. The specific embodiments are only for the purposes of description, and are not limited to these practical details thereof.

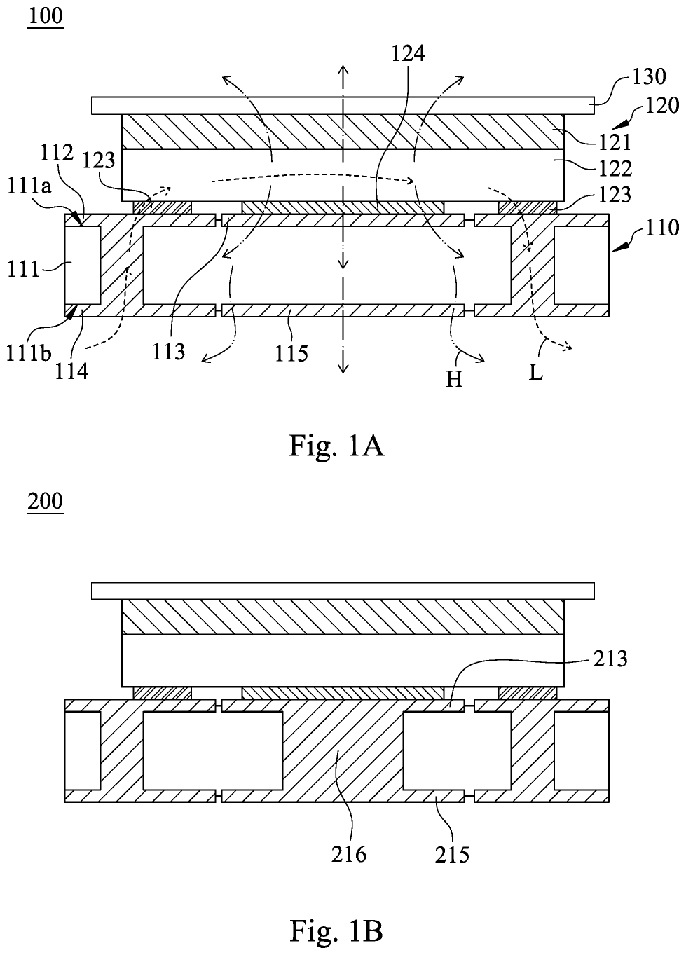

Please refer to FIG. 1A. FIG. 1A is a cross-sectional schematic view of the semiconductor power device 100 according to the 1st embodiment of the present disclosure. According to the 1st embodiment of the present disclosure, the semiconductor power device 100 is provided. The semiconductor power device 100 includes a ceramic-metal composite circuit substrate 110, a flip chip 120 and a metal thermal-conducting layer 130. The flip chip 120 is disposed on the ceramic-metal composite circuit substrate 110, and the metal thermal-conducting layer 130 is disposed on the flip chip 120, which makes the flip chip 120 be arranged between the metal thermal-conducting layer 130 and the ceramic-metal composite circuit substrate 110.

In detail, the ceramic-metal composite circuit substrate 110 includes a ceramic insulating layer 111, a plurality of first electric-conducting metal pads 112 and at least one first thermal-conducting metal pad 113. The ceramic insulating layer 111 has a first side 111a and a second side 111b opposite to the first side 111a. The first electric-conducting metal pads 112 and the first thermal-conducting metal pad 113 are all disposed on the first side 111a of the ceramic insulating layer 111. The first electric-conducting metal pads 112 are configured for conducting the current of the flip chip 120. The first thermal-conducting metal pad 113 is configured for absorbing and transferring the heat generated by the flip chip 120, so as to facilitate the heat dissipation of the flip chip 120.

The ceramic-metal composite circuit substrate 110 can have a ceramic material and a metal material, the ceramic material can be selected from the group consisting of aluminum oxide (Al₂O₃), aluminum nitride (AlN) and silicon nitride (Si₃N₄), and the metal material can be selected from the group consisting of copper, aluminum, silver and gold.

In detail, the ceramic-metal composite circuit substrate 110 can be formed by direct bonding copper (DBC) on an aluminum oxide substrate or an aluminum nitride substrate. Alternatively, the ceramic-metal composite circuit substrate 110 can be formed by direct plating copper (DPC) on the aluminum oxide substrate, the aluminum nitride substrate or a silicon nitride substrate. Alternatively, the ceramic-metal composite circuit substrate 110 can be formed by active metal brazing (AMB) on the silicon nitride substrate to make copper bond to the silicon nitride substrate. The ceramic-metal composite circuit substrate 110 manufactured by active metal brazing has good heat resistance and shock resistance, and can maintain good mechanical properties at high temperatures. As the power increases, the ceramic-metal composite circuit substrate 110 manufactured by active metal brazing is more resistant to high cold impact and is more suitable for bonding with thicker copper layers to facilitate heat dissipation. The metal layers (such as copper metal) combines thereto can be larger than 800 μm, and can be larger than 1500 μm. The type of the ceramic-metal composite circuit substrate 110 can be selected according to the operation power.

The flip chip 120 is arranged at the first side 111a of the ceramic insulating layer 111. The flip chip 120 includes a substrate 121, a semiconductor structural layer 122, a plurality of electric-conducting pads 123 and at least one floating thermal-conducting metal pad 124. The semiconductor structural layer 122 is disposed on the substrate 121, and the electric-conducting pads 123 and the floating thermal-conducting metal pad 124 are all disposed on the semiconductor structural layer 122. The floating thermal-conducting metal pad 124 is connected to the first thermal-conducting metal pad 113, which makes the semiconductor structural layer 122 be arranged between the substrate 121 and the electric-conducting pads 123, and be arranged between the substrate 121 and the floating thermal-conducting metal pad 124.

The electric-conducting pads 123 of the flip chip 120 are electrically connected to the semiconductor structural layer 122 and the first electric-conducting metal pads 112. Therefore, current can be transferred between the flip chip 120 and the ceramic-metal composite circuit substrate 110 through the electric-conducting pads 123. It should be mentioned that, the first thermal-conducting metal pad 113 of the ceramic-metal composite circuit substrate 110 is not electrically connected to each of the first electric-conducting metal pads 112, and the floating thermal-conducting metal pad 124 of the flip chip 120 is not electrically connected to the electric-conducting pads 123 and the semiconductor structural layer 122, so as to prevent current passing through the first thermal-conducting metal pad 113 and the floating thermal-conducting metal pad 124.

In other words, when the flip chip 120 is powered, the floating thermal-conducting metal pad 124 and the first thermal-conducting metal pad 113 do not directly affect the operation of the flip chip 120. In this regard, the first thermal-conducting metal pad 113 and the floating thermal-conducting metal pad 124 are only for transferring heat, which ensures that the heat transferring efficiency thereof does not affected by current, and the effect of separating the heat transferring path and the electric transferring path can be obtained.

An area of the flip chip 120 can be 4 mm² to 400 mm², and a power of the flip chip 120 can be larger than or equal to 100 watts. The operation power is preferably between 100 watts to 2000 watts. A material of the flip chip 120 can be selected from the group consisting of gallium nitride, indium gallium nitride (InGaN), aluminum gallium nitride (GaAlN), and indium aluminum gallium nitride (InGaAlN), or other nitride materials with wide band gap. Therefore, the semiconductor power device 100 can be applied to products with high-voltage, high-current, and high-wattage, and has great heat dissipating efficiency.

Moreover, the ceramic-metal composite circuit substrate 110 can further include a plurality of second electric-conducting metal pads 114 and at least one second thermal-conducting metal pad 115. The second electric-conducting metal pads 114 and the second thermal-conducting metal pad 115 are all disposed on the second side 111b of the ceramic insulating layer 111. The second electric-conducting metal pads 114 are respectively electrically connected to the first electric-conducting metal pads 112. Through the second electric-conducting metal pads 114 and the second thermal-conducting metal pad 115, current and heat can be further transferred to the outside of the semiconductor power device 100. Furthermore, the second thermal-conducting metal pad 115 is not electrically connected to each of the second electric-conducting metal pads 114. The second thermal-conducting metal pad 115 is not for the electrical functions of the flip chip 120, but is only for electrical grounding at most. Therefore, the heat transferring path and the electric transferring path can be separated, and the operation of the flip chip 120 is not directly affected by the second thermal-conducting metal pad 115.

It should be mentioned that, the ceramic insulating layer 111 not only has insulating property to make sure that current only flows between the first electric-conducting metal pads 112 and the second electric-conducting metal pads 114, the ceramic insulating layer 111 but also has heat-conducting ability. Therefore, heat can arrive at the second thermal-conducting metal pad 115 from the first thermal-conducting metal pad 113 through the ceramic insulating layer 111, and then be dissipated.

In order to clearly explain the transferring process of heat and electric in the semiconductor power device 100, the heat transferring path H and the electric transferring path L of the semiconductor power device 100 are illustrated in FIG. 1A. Please refer to the electric transferring path L. Current enters the semiconductor power device 100 through one of the second electric-conducting metal pads 114, and leaves the semiconductor power device 100 through another one of the second electric-conducting metal pads 114 after passing through the flip chip 120.

Then, please refer to the heat transferring path H. Massive heat generated in the operation of the flip chip 120 can be transferred outwardly through the first thermal-conducting metal pad 113, the ceramic insulating layer 111 and the second thermal-conducting metal pad 115. Due to the separation of the heat transferring path H and the electric transferring path L, heat can be effectively dissipated to ensure that the semiconductor power device 100 is not easily overheating and damaged under high-power operation.

Although the heat and electric transfer in the semiconductor power device 100 is illustrated by the heat transferring path H and the electric transferring path L in FIG. 1A, but the heat and electric actually enter or leave the semiconductor power device 100 along different paths in different operations. For example, if an alternating current is applied to the semiconductor power device 100, the direction of the electric transferring path L periodically reverses. Moreover, even most heat leaves the semiconductor power device 100 along the heat transferring path H, there is still a little of heat transferring along the electric transferring path L or other paths. Therefore, the present disclosure is not limited to the heat transferring path H and the electric transferring path L in FIG. 1A.

In addition to the heat transferring path H, heat dissipation of the semiconductor power device 100 can also be performed by the metal thermal-conducting layer 130. The metal thermal-conducting layer 130 is disposed on the substrate 121 of the flip chip 120. Therefore, the metal thermal-conducting layer 130 and the ceramic-metal composite circuit substrate 110 are respectively located on the two sides of the flip chip 120 to facilitate heat dissipation, which significantly improves the heat dissipating efficiency of the semiconductor power device 100.

In order to improve the transferring efficiency of heat and electric and prevent damage of high-temperature, metal bonds can be formed between the electric-conducting pads 123 and the first electric-conducting metal pads 112, between the floating thermal-conducting metal pad 124 and the first thermal-conducting metal pad 113, and between the metal thermal-conducting layer 130 and the substrate 121 for connection. Alternatively, all of the other connections between metal elements in the semiconductor power device 100 can be achieved by forming metal bonds. The metal bonds can be formed by a metal eutectic method or a metal sintering method. The metal sintering method can be silver sintering or copper sintering, and a material of the metal sintering method can be selected from the group consisting of silver metal particles, copper metal particles and silver-indium alloy particles, preferably from the group consisting of silver nano-particles, copper nano-particles and silver-indium alloy particles. A material of the metal eutectic method can be selected from the group consisting of gold, gold/tin, tin/silver/bismuth, tin/silver/bismuth/copper and tin/silver/copper.

Please refer to FIG. 1B. FIG. 1B is a cross-sectional schematic view of the semiconductor power device 200 according to the 2nd embodiment of the present disclosure. The semiconductor power device 200 of the 2nd embodiment of the present disclosure is similar to the semiconductor power device 100 of the 1st embodiment. The difference is that, the first thermal-conducting metal pad 213 and the second thermal-conducting metal pad 215 of the semiconductor power device 200 are connected by a thermal-conducting element 216, which helps heat move from the first thermal-conducting metal pad 213 to the second thermal-conducting metal pad 215 more rapidly, so the heat dissipating efficiency can be further improved.

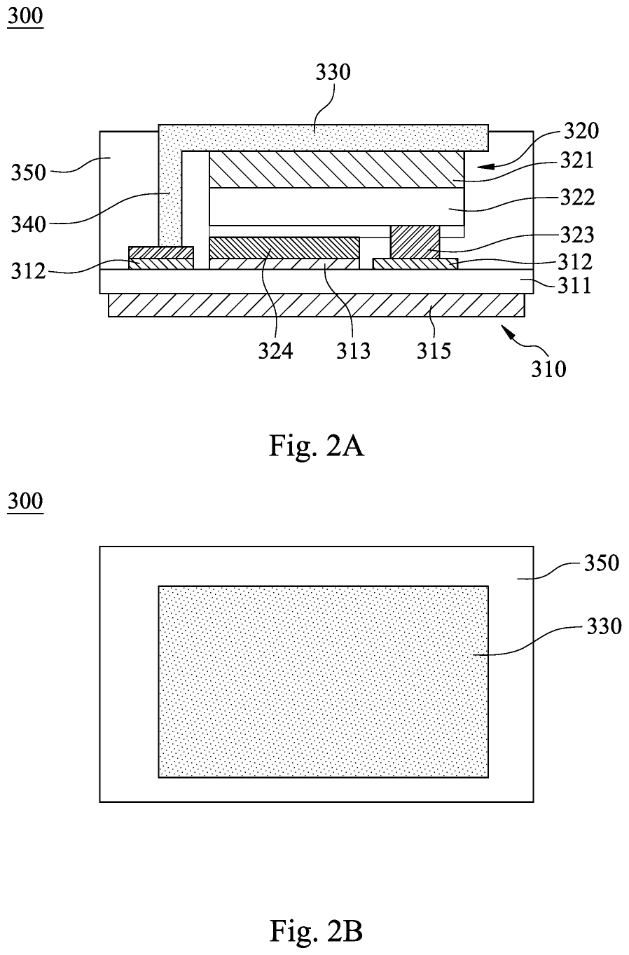

Please refer to FIG. 2A. FIG. 2A is a cross-sectional schematic view of the semiconductor power device 300 according to the 3rd embodiment of the present disclosure. The semiconductor power device 300 of the 3rd embodiment includes a ceramic-metal composite circuit substrate 310, a flip chip 320 and a metal thermal-conducting layer 330. The flip chip 320 is disposed on the ceramic-metal composite circuit substrate 310, and the metal thermal-conducting layer 330 is disposed on the flip chip 320.

In short, the ceramic-metal composite circuit substrate 310 includes a ceramic insulating layer 311, a plurality of (for example, four) first electric-conducting metal pads 312 and a first thermal-conducting metal pad 313. The flip chip 320 includes a substrate 321, a semiconductor structural layer 322, a plurality of (for example, three) electric-conducting pads 323 and a floating thermal-conducting metal pad 324. The three electric-conducting pads 323 of the flip chip 320 are respectively electrically connected to three of the first electric-conducting metal pads 312. The metal thermal-conducting layer 330 is disposed on the substrate 321 of the flip chip 320.

It should be noticed that, the substrate 321 of the 3rd embodiment can not only be a non-conductive substrate, but can also be a non-insulating substrate. Specifically, the substrate 321 can be a semiconductor substrate, such as a silicon substrate, but the present disclosure is not limited thereto. Because the substrate 321 can be the semiconductor substrate, the substrate 321 includes a plurality of carriers, such as electrons or electron holes. The semiconductor power device 300 further includes a metal conductive element 340, and the metal conductive element 340 is electrically connected to the metal thermal-conducting layer 330 and another one of the first electric-conducting metal pads 312. The another one of the first electric-conducting metal pads 312 can be grounding, so as to make the carriers in the substrate 321 be neutralized by the metal conductive element 340 and the metal thermal-conducting layer 330. In other embodiments, the metal conductive element does not need to be electrically connected to the metal thermal-conducting layer and the first electric-conducting metal pads at the same time, and the connections therebetween are not limited in the present disclosure.

Please also refer to FIG. 2B. FIG. 2B is a top schematic view of the semiconductor power device 300 of FIG. 2A. The semiconductor power device 300 of the 3rd embodiment can further include a packaging layer 350, which is disposed on the first side of the ceramic insulating layer 311, and covers the flip chip 320. The packaging layer 350 can cover a side of the metal thermal-conducting layer 330, but does not cover a surface of the metal thermal-conducting layer 330 away from the flip chip 320. The surface of the metal thermal-conducting layer 330 away from the flip chip 320 can be exposed as FIG. 2B, so the packaging layer 350 can effectively protect the connecting parts between the flip chip 320 and other elements. It should be mentioned that, although the detailed technical features of the packaging layer 350 are only given in the 3rd embodiment of the present disclosure, the packaging layer 350 can be applied to different examples with a same or similar way. A material of the packaging layer 350 can be a polymer resin material, or can mainly be the polymer resin with the addition of heat-conducting powder material to enhance heat conductivity. The heat-conducting powder material can be, for example, ceramic-type materials such as aluminum nitride, aluminum oxide, boron nitride or graphene.

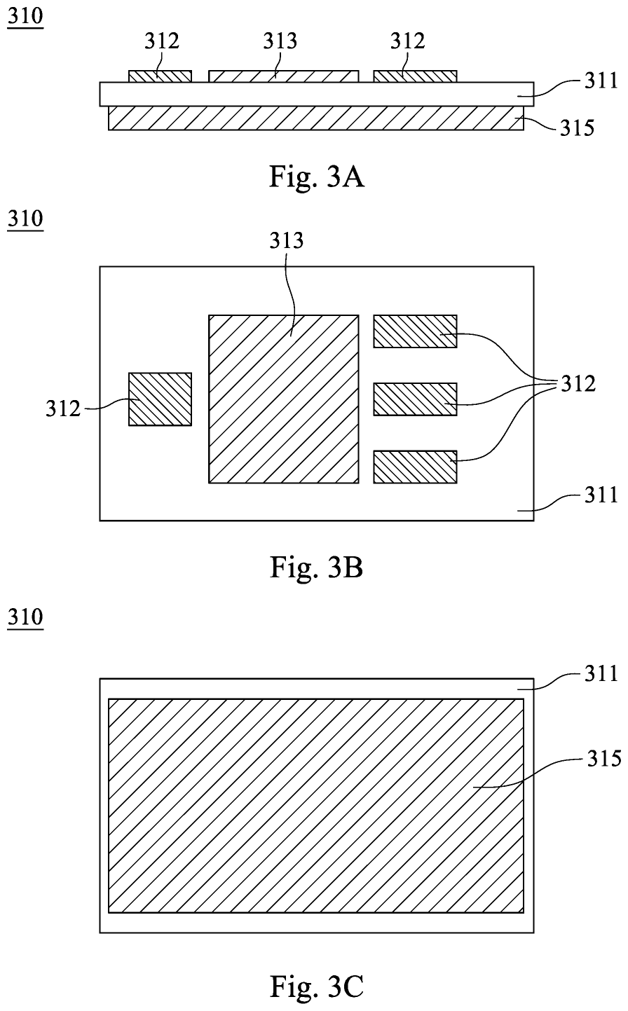

Please refer to FIG. 3A and FIG. 3B. FIG. 3A is a cross-sectional schematic view of the ceramic-metal composite circuit substrate 310 according to the 3rd embodiment of the present disclosure. FIG. 3B is a top schematic view of the ceramic-metal composite circuit substrate 310 of FIG. 3A. The four first electric-conducting metal pads 312 and the first thermal-conducting metal pad 313 of the ceramic-metal composite circuit substrate 310 of the 3rd embodiment are arranged as FIG. 3A and FIG. 3B. In the 3rd embodiment, the ceramic-metal composite circuit substrate 310 can only include the second thermal-conducting metal pad 315 but not include second electric-conducting metal pad. Therefore, the four first electric-conducting metal pads 312 can be directly connected to outer circuit, so as to simplify the structural design of the ceramic-metal composite circuit substrate 310.

Please refer to FIG. 3C. FIG. 3C is a bottom schematic view of the ceramic-metal composite circuit substrate 310 of FIG. 3A. Because the ceramic-metal composite circuit substrate 310 does not include second electric-conducting metal pad, an area of the second thermal-conducting metal pad 315 is larger, which can effectively improve the heat dissipating effect.

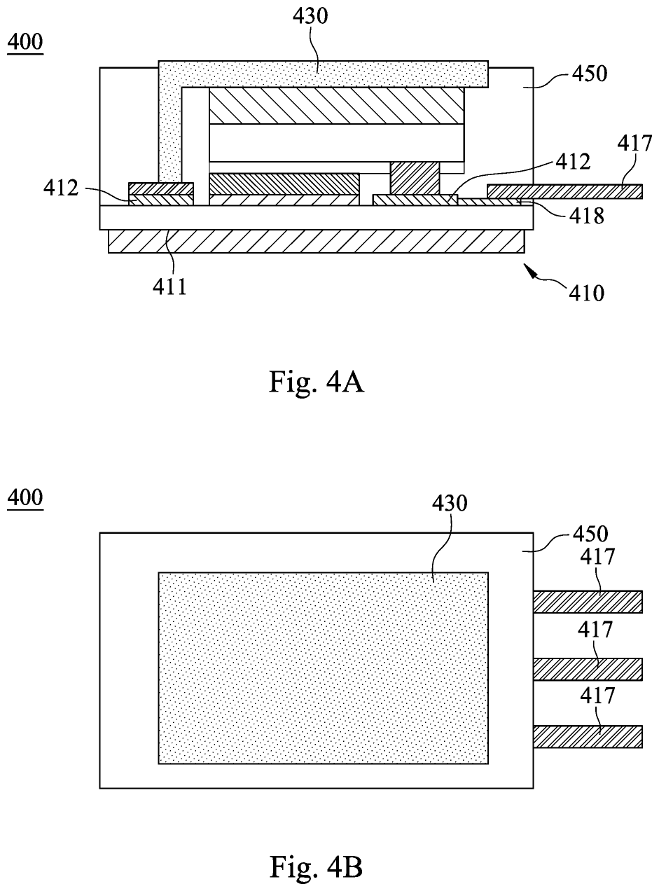

Please refer to FIG. 4A. FIG. 4A is a cross-sectional schematic view of the semiconductor power device 400 according to the 4th embodiment of the present disclosure. The semiconductor power device 400 of the 4th embodiment is similar to the semiconductor power device 300 of the 3rd embodiment. The difference is that, the ceramic-metal composite circuit substrate 410 of the semiconductor power device 400 further includes a plurality of metal leads 417. In the 4th embodiment, a number of the first electric-conducting metal pads 412 is four. One of the first electric-conducting metal pads 412 is for the grounding of the metal thermal-conducting layer 430, so the corresponding metal leads 417 are three. However, the present disclosure is not limited to the number of the metal leads 417.

Please also refer to FIG. 4B. FIG. 4B is a top schematic view of the semiconductor power device 400 of FIG. 4A. The metal leads 417 are disposed on the first side of the ceramic insulating layer 411, and the metal leads 417 are respectively electrically connected to the first electric-conducting metal pads 412. Therefore, part of the metal leads 417 can be exposed from the packaging layer 450 as packaging, and the metal leads 417 can be pins for direct insertion.

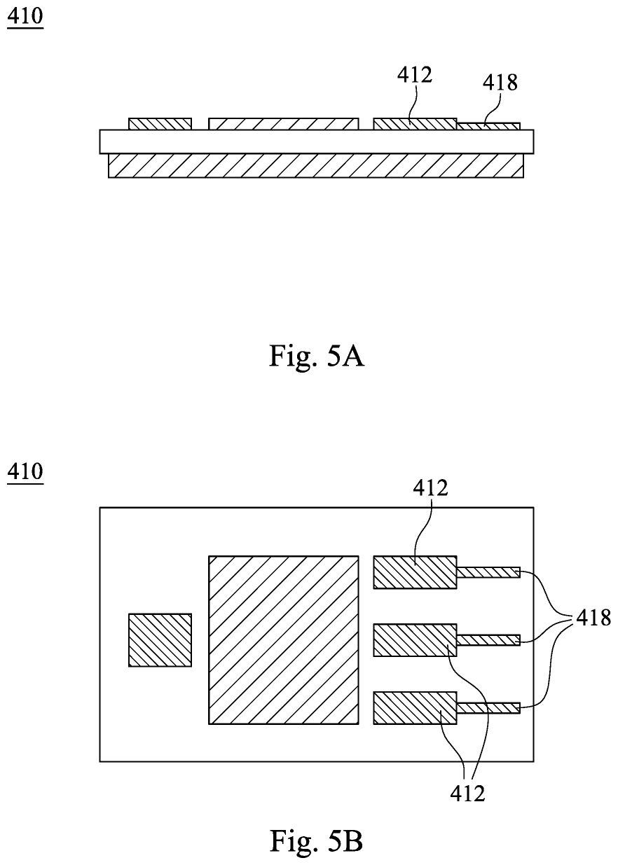

Please refer to FIG. 5A and FIG. 5B. FIG. 5A is a cross-sectional schematic view of the ceramic-metal composite circuit substrate 410 according to the 4th embodiment of the present disclosure. FIG. 5B is a top schematic view of the ceramic-metal composite circuit substrate 410 of FIG. 5A. The ceramic-metal composite circuit substrate 410 can further include a plurality of (for example, three) extension portions 418. Each of the extension portions 418 is connected to the corresponding one of the first electric-conducting metal pads 412, and arbitrarily extended on the ceramic-metal composite circuit substrate 410. The metal leads 417 are electrically connected to the first electric-conducting metal pads 412 through the extension portions 418, so as to enhance the flexibility of arranging the metal leads 417.

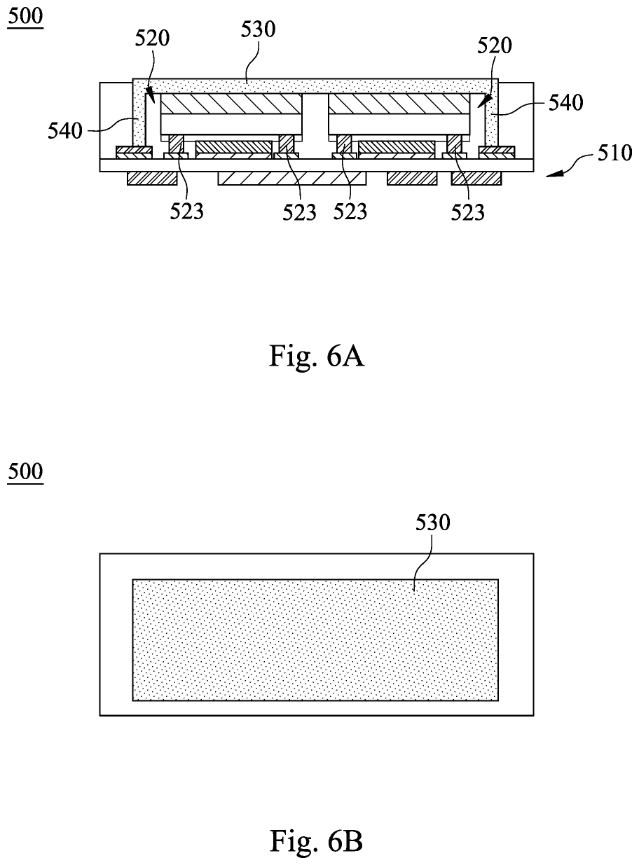

Please refer to FIG. 6A and FIG. 6B. FIG. 6A is a cross-sectional schematic view of the semiconductor power device 500 according to the 5th embodiment of the present disclosure. FIG. 6B is a top schematic view of the semiconductor power device 500 of FIG. 6A. The semiconductor power device 500 of the 5th embodiment includes a ceramic-metal composite circuit substrate 510, a plurality of (for example, two) flip chips 520 and a metal thermal-conducting layer 530. The flip chips 520 are disposed on the ceramic-metal composite circuit substrate 510, and the metal thermal-conducting layer 530 is disposed on the flip chips 520. In FIG. 6A and FIG. 6B, the metal thermal-conducting layer 530 on the flip chips 520 is integral, and is electrically connected to the two metal conductive elements 540 at the two sides of the flip chips 520. Therefore, the metal thermal-conducting layer 530 has larger area for heat dissipation.

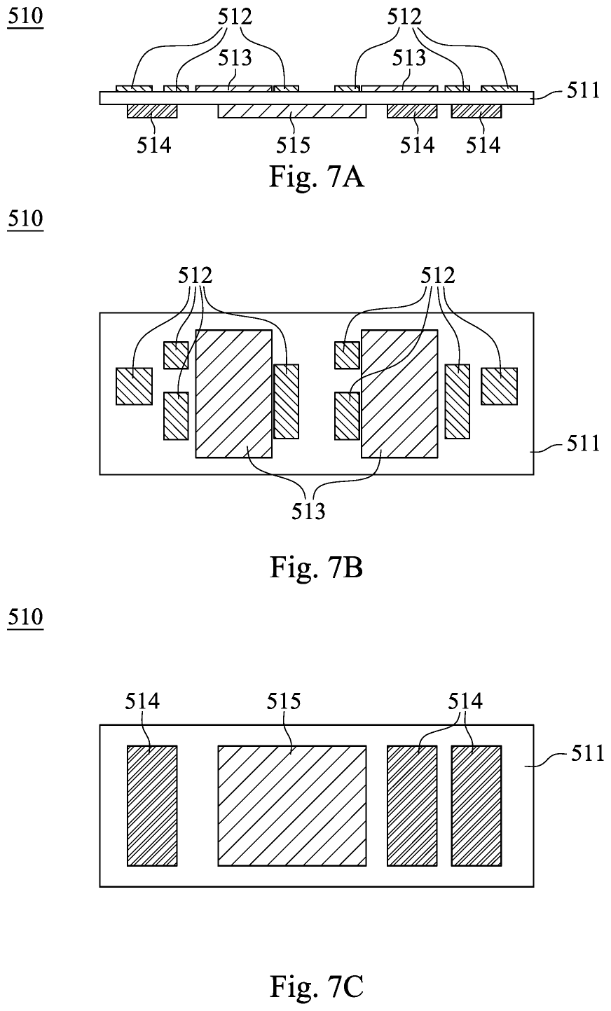

Please refer to FIG. 7A and FIG. 7B. FIG. 7A is a cross-sectional schematic view of the ceramic-metal composite circuit substrate 510 according to the 5th embodiment of the present disclosure. FIG. 7B is a top schematic view of the ceramic-metal composite circuit substrate 510 of FIG. 7A. The ceramic-metal composite circuit substrate 510 includes a ceramic insulating layer 511, a plurality of (for example, eight) first electric-conducting metal pads 512 and at least one (for example, two) first thermal-conducting metal pad 513. That is, each of the flip chips 520 is corresponding to four of the first electric-conducting metal pads 512 and one of the first thermal-conducting metal pads 513.

Please refer to FIG. 7C. FIG. 7C is a bottom schematic view of the ceramic-metal composite circuit substrate 510 of FIG. 7A. The ceramic-metal composite circuit substrate 510 further includes a plurality of (for example, three) second electric-conducting metal pads 514 and a second thermal-conducting metal pad 515. The second electric-conducting metal pads 514 and the second thermal-conducting metal pad 515 are all disposed on the second side of the ceramic insulating layer 511. Therefore, the semiconductor power device 500 can be connected to outer circuit through the second electric-conducting metal pads 514.

It should be mentioned that, in the 5th embodiment or other embodiments, each of the flip chips 520 can be a horizontal chip. That is, each of the flip chips 520 can include three electric-conducting pads 523, which respectively are a gate electrode, a drain electrode and a source electrode. Four of the first electric-conducting metal pads 512 are corresponding to each of the flip chips 520, one of the four first electric-conducting metal pads 512 can be configured for grounding of the metal thermal-conducting layer 530, and other three of the four first electric-conducting metal pads 512 are respectively electrically connected to the gate electrode, the drain electrode and the source electrode of the flip chips 520. Furthermore, in other embodiments, numbers of the gate electrode, the drain electrode and the source electrode of the flip chip can be adjusted to meet the requirements. That is, the electric-conducting pads of the flip chip can include at least one gate electrode, at least one drain electrode and at least one source electrode, and the present disclosure is not limited to the numbers thereof. For example, when the semiconductor power device is a transistor, the plurality of electric-conducting pads can include at least one gate electrode, at least one drain electrode and at least one source electrode. When the semiconductor power device is a diode, the plurality of electric-conducting pads can include at least one drain electrode and at least one source electrode.

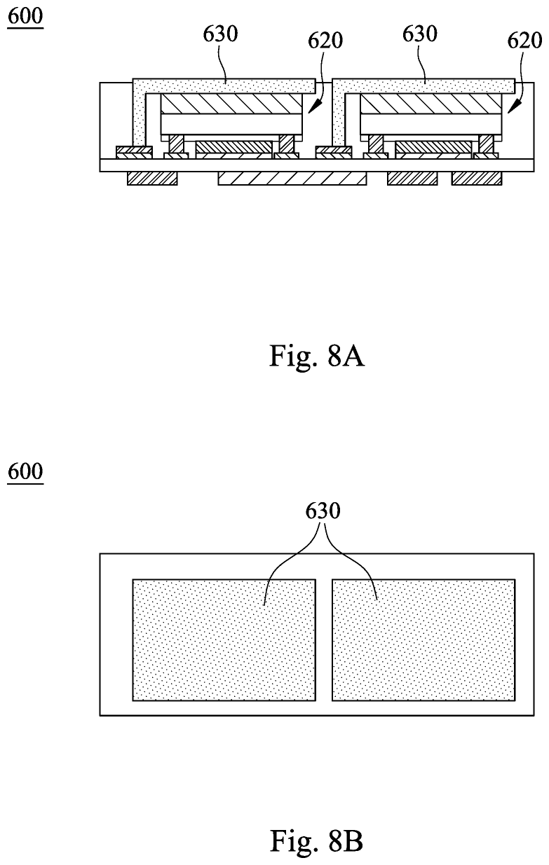

Please refer to FIG. 8A and FIG. 8B. FIG. 8A is a cross-sectional schematic view of the semiconductor power device 600 according to the 6th embodiment of the present disclosure. FIG. 8B is a top schematic view of the semiconductor power device 600 of FIG. 8A. The semiconductor power device 600 of the 6th embodiment is similar to the semiconductor power device 500 of the 5th embodiment. The difference is that, the semiconductor power device 600 includes a plurality of (for example, two) metal thermal-conducting layers 630, which are respectively disposed on the two flip chips 620. In FIG. 8B, the metal thermal-conducting layers 630 are separated from each other and not integral, so the flexibility of arranging the flip chips 620 can be enhanced.

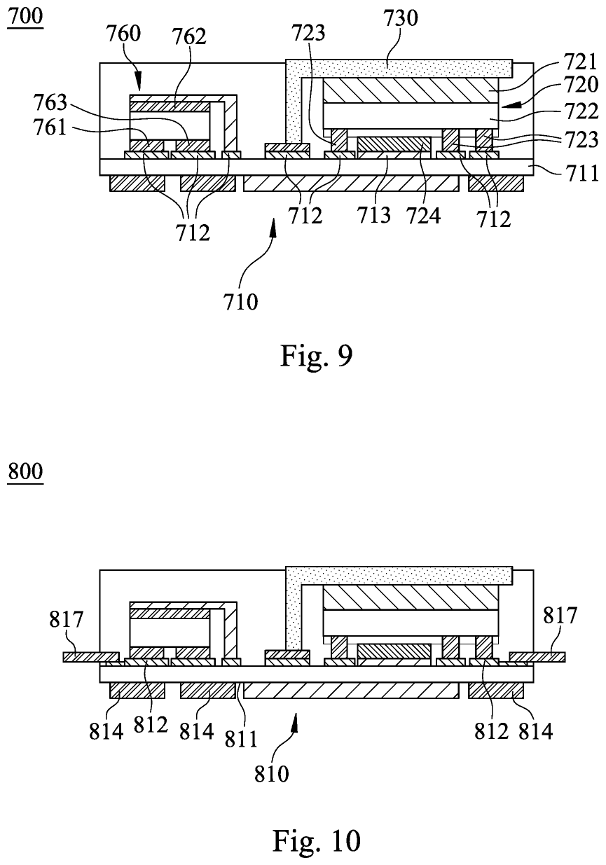

Please refer to FIG. 9. FIG. 9 is a cross-sectional schematic view of the semiconductor power device 700 according to the 7th embodiment of the present disclosure. The semiconductor power device 700 of the 7th embodiment includes a ceramic-metal composite circuit substrate 710, a flip chip 720, a metal thermal-conducting layer 730 and a vertical transistor 760. The vertical transistor 760 can be a silicon power element, or can be a silicon carbide power element. The flip chip 720 and the vertical transistor 760 are disposed on the ceramic-metal composite circuit substrate 710. The flip chip 720 and the vertical transistor 760 are electrically connected to each other by the circuit design on the ceramic-metal composite circuit substrate 710, which makes the flip chip 720 and the vertical transistor 760 perform with a cascode function, and the metal thermal-conducting layer 730 is disposed on the flip chip 720.

In short, the ceramic-metal composite circuit substrate 710 includes a ceramic insulating layer 711, a plurality of (for example, seven) first electric-conducting metal pads 712 and a first thermal-conducting metal pad 713. The flip chip 720 includes a substrate 721, a semiconductor structural layer 722, a plurality of (for example, three) electric-conducting pads 723 and a floating thermal-conducting metal pad 724. The three electric-conducting pads 723 of the flip chip 720 are respectively electrically connected to three of the first electric-conducting metal pads 712. The metal thermal-conducting layer 730 is disposed on the substrate 721 of the flip chip 720, and electrically connected to another one of the first electric-conducting metal pads 712.

The vertical transistor 760 is arranged at the first side of the ceramic-metal composite circuit substrate 710. The vertical transistor 760 includes a gate electrode 761, a drain electrode 762 and a source electrode 763. The gate electrode 761 and the source electrode 763 are arranged on a side of the vertical transistor 760 adjacent to the ceramic-metal composite circuit substrate 710, and the drain electrode 762 is arranged on a side of the vertical transistor 760 away from the ceramic-metal composite circuit substrate 710. The gate electrode 761, the drain electrode 762 and the source electrode 763 of the vertical transistor 760 are respectively electrically connected to another three of the first electric-conducting metal pads 712. In this regard, no matter the chip element is a horizontal type or a vertical type, the horizontal and vertical chip elements can be applied to the semiconductor power device of the present disclosure.

Please refer to FIG. 10. FIG. 10 is a cross-sectional schematic view of the semiconductor power device 800 according to the 8th embodiment of the present disclosure. The semiconductor power device 800 of the 8th embodiment is similar to the semiconductor power device 700 of the 7th embodiment. The difference is that, the ceramic-metal composite circuit substrate 810 of the semiconductor power device 800 further includes a plurality of metal leads 817. The metal leads 817 are disposed on the first side of the ceramic insulating layer 811, and the metal leads 817 are respectively electrically connected to the first electric-conducting metal pads 812, so the metal leads 817 can be pins for direct insertion. Please be noted that, the ceramic-metal composite circuit substrate 810 can include a plurality of second electric-conducting metal pads 814 and the metal leads 817 at the same time. The plurality of second electric-conducting metal pads 814 are disposed on the second side of the ceramic insulating layer 811, and the plurality of second electric-conducting metal pads 814 are respectively electrically connected to the plurality of first electric-conducting metal pads 812. Therefore, the semiconductor power device 800 can be electrically connected to other components through the plurality of second electric-conducting metal pads 814 and the metal leads 817.

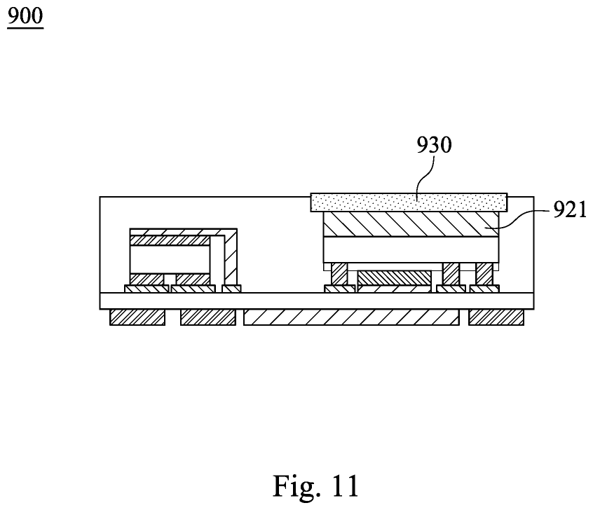

Please refer to FIG. 11. FIG. 11 is a cross-sectional schematic view of the semiconductor power device 900 according to the 9th embodiment of the present disclosure. The semiconductor power device 900 of the 9th embodiment is similar to the semiconductor power device 700 of the 7th embodiment. The difference is that, the substrate 921 of the semiconductor power device 900 is an insulating substrate. Therefore, the substrate 921 does not include carrier, the metal thermal-conducting layer 930 does not need to be connected to a metal conductive element or grounding. The substrate 921 can be a sapphire substrate, a silicon substrate, a silicon-silicon oxide composite insulating substrate, a silicon-aluminum nitride composite insulating substrate or substrates made of other insulating materials.

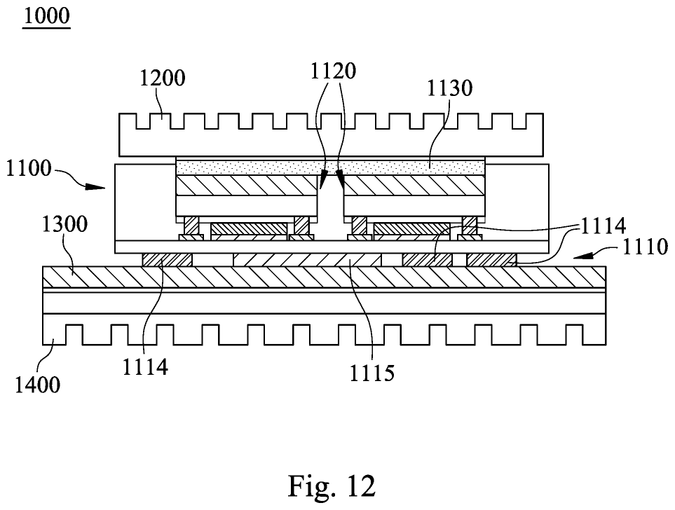

Please refer to FIG. 12. FIG. 12 is a cross-sectional schematic view of the semiconductor module 1000 according to the 10th embodiment of the present disclosure. The semiconductor module 1000 of the 10th embodiment includes a semiconductor power device 1100, a cooling fin 1200, a circuit board 1300 and a water-cooling plate 1400. The semiconductor power device 1100 is disposed on the circuit board 1300 and electrically connected to the circuit board 1300. The cooling fin 1200 is disposed on the semiconductor power device 1100, and the circuit board 1300 is disposed on the water-cooling plate 1400. Therefore, the semiconductor power device 1100 is arranged between the cooling fin 1200 and the circuit board 1300, and the circuit board 1300 is arranged between the semiconductor power device 1100 and the water-cooling plate 1400.

In detail, the semiconductor power device 1100 includes a ceramic-metal composite circuit substrate 1110, a plurality of (for example, two) flip chips 1120 and a metal thermal-conducting layer 1130. The flip chips 1120 are disposed on the ceramic-metal composite circuit substrate 1110, and the metal thermal-conducting layer 1130 is disposed on the flip chips 1120. In FIG. 12, the metal thermal-conducting layer 1130 on the flip chips 1120 is integral, and a metal conductive element does not need to be arranged for grounding of the metal thermal-conducting layer 1130.

The ceramic-metal composite circuit substrate 1110 further includes a plurality of (for example, three) second electric-conducting metal pads 1114 and a second thermal-conducting metal pad 1115. The second electric-conducting metal pads 1114 and the second thermal-conducting metal pad 1115 are all connected to the circuit board 1300 to transfer heat or electric. Moreover, the semiconductor power device 1100 is connected to the cooling fin 1200 through the metal thermal-conducting layer 1130, and metal bonds can also be formed between the metal thermal-conducting layer 1130 and the cooling fin 1200 and between the circuit board 1300 and the water-cooling plate 1400 for connection. Therefore, the heat dissipating efficiency of the semiconductor power device 1100 can be further enhanced by the cooling fin 1200 and the water-cooling plate 1400.

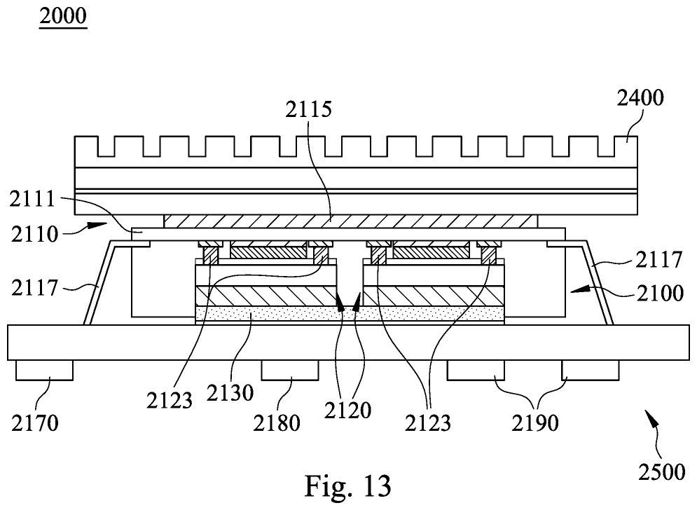

Please refer to FIG. 13. FIG. 13 is a cross-sectional schematic view of the semiconductor module 2000 according to the 11th embodiment of the present disclosure. The semiconductor module 2000 includes a semiconductor power device 2100 and a driving circuit substrate 2500. In detail, the semiconductor power device 2100 includes a ceramic-metal composite circuit substrate 2110, a plurality of semiconductor devices (its number is omitted) and a metal thermal-conducting layer 2130. The semiconductor devices include at least one (for example, two) flip chip 2120. The flip chips 2120 are disposed on the ceramic-metal composite circuit substrate 2110, and the metal thermal-conducting layer 2130 is disposed on the flip chips 2120. The ceramic-metal composite circuit substrate 2110 includes at least one second thermal-conducting metal pad 2115. The second thermal-conducting metal pad 2115 is disposed on the second side of the ceramic insulating layer 2111, so as to connect the semiconductor power device 2100 and outer thermal conducting elements (such as a water-cooling plate 2400). The ceramic-metal composite circuit substrate 2110 can be without electric-conducting metal pad, so as to enhance the area and the heat-conducting effect of the second thermal-conducting metal pad 2115. The ceramic-metal composite circuit substrate 2110 includes a plurality of metal leads 2117. The plurality of metal leads 2117 are disposed on the first side of the ceramic insulating layer 2111, and respectively electrically connected to the plurality of first electric-conducting metal pads.

The driving circuit substrate 2500 is electrically connected to the plurality of metal leads 2117, the plurality of first electric-conducting metal pads (not shown) or the plurality of electric-conducting pads 2123. In detail, the driving circuit substrate 2500 can be connected to the metal thermal-conducting layer 2130, wherein the metal thermal-conducting layer 2130 is arranged between the flip chips 2120 and the driving circuit substrate 2500. The semiconductor module 2000 can further include a thermal-conducting plate (not shown), and the driving circuit substrate 2500 is connected to the at least one second thermal-conducting metal pad 2115 through the thermal-conducting plate. In other embodiments, the driving circuit substrate is not directly connected to the metal thermal-conducting layer, but can be connected to the metal thermal-conducting layer through the thermal-conducting plate.

The driving circuit substrate 2500 can be an insulated metal substrate (IMS) or a ceramic metal substrate. The driving circuit substrate 2500 can include a driving element 2170, an integrated circuit element 2180 and two passive elements 2190, as shown in FIG. 13, which can be disposed on a side of the driving circuit substrate 2500 away from the semiconductor power device 2100, or can be disposed on a side of the driving circuit substrate 2500 adjacent to the semiconductor power device 2100, which is not limited to being disposed on the same side. Therefore, most of the heat generated by the operation of the semiconductor power device 2100 is transferred outwardly by the second thermal-conducting metal pad 2115, and a small amount of the heat is transferred outwardly by the driving circuit substrate 2500. The driving circuit substrate 2500 is mainly responsible for processing the electrical signals, so the heat dissipation efficiency can be further improved.

In this regard, the semiconductor power device of the present disclosure makes massive heat generated in the high-power operation of the flip chip be dissipated outwardly and simultaneously from both sides of the flip chip by arranging the first thermal-conducting metal pad, the floating thermal-conducting metal pad and the metal thermal-conducting layer. Moreover, by the first thermal-conducting metal pad without electrically connected to the first electric-conducting metal pads, and by the floating thermal-conducting metal pad only connected to the first thermal-conducting metal pad but without electrically connected to the electric-conducting pads and the semiconductor structural layer, it ensures that the heat transferring effect thereof does not affected by current. Therefore, the semiconductor power device of the present disclosure has great heat dissipating efficiency.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor power device, comprising:
a ceramic-metal composite circuit substrate, comprising:
a ceramic insulating layer, having a first side and a second side opposite to the first side;
a plurality of first electric-conducting metal pads, disposed on the first side of the ceramic insulating layer; and
at least one first thermal-conducting metal pad, which is disposed on the first side of the ceramic insulating layer, and not electrically connected to each of the plurality of first electric-conducting metal pads;
a flip chip, disposed on the ceramic-metal composite circuit substrate, and arranged at the first side, wherein the flip chip comprises:
a substrate;
a semiconductor structural layer, disposed on the substrate;
a plurality of electric-conducting pads, disposed on the semiconductor structural layer, and electrically connected to the semiconductor structural layer and the plurality of first electric-conducting metal pads, wherein the semiconductor structural layer is arranged between the substrate and the plurality of electric-conducting pads; and
at least one floating thermal-conducting metal pad, disposed on the semiconductor structural layer, and connected to the at least one first thermal-conducting metal pad, wherein the semiconductor structural layer is arranged between the substrate and the at least one floating thermal-conducting metal pad, and the at least one floating thermal-conducting metal pad is not electrically connected to the plurality of electric-conducting pads and the semiconductor structural layer; and
a metal thermal-conducting layer, disposed on the substrate.

2. The semiconductor power device of claim 1, wherein the substrate is a sapphire substrate, a silicon substrate, a silicon-silicon oxide composite insulating substrate or a silicon-aluminum nitride composite insulating substrate.

3. The semiconductor power device of claim 1, wherein the semiconductor power device further comprises a metal conductive element, and the metal conductive element is electrically connected to the metal thermal-conducting layer.

4. The semiconductor power device of claim 1, wherein the semiconductor power device further comprises a metal conductive element, and the metal conductive element is electrically connected to one of the plurality of first electric-conducting metal pads.

5. The semiconductor power device of claim 1, wherein the ceramic-metal composite circuit substrate further comprises a plurality of second electric-conducting metal pads, which are disposed on the second side of the ceramic insulating layer, and the plurality of second electric-conducting metal pads are respectively electrically connected to the plurality of first electric-conducting metal pads.

6. The semiconductor power device of claim 5, wherein the ceramic-metal composite circuit substrate further comprises at least one second thermal-conducting metal pad, which is disposed on the second side of the ceramic insulating layer, and not electrically connected to each of the plurality of second electric-conducting metal pads.

7. The semiconductor power device of claim 6, further comprising:
a packaging layer, disposed on the first side of the ceramic insulating layer, and covering the flip chip, wherein the packaging layer covers a side of the metal thermal-conducting layer, but does not cover a surface of the metal thermal-conducting layer away from the flip chip.

8. The semiconductor power device of claim 1, wherein metal bonds are formed between the plurality of electric-conducting pads and the plurality of first electric-conducting metal pads, between the at least one floating thermal-conducting metal pad and the at least one first thermal-conducting metal pad, and between the metal thermal-conducting layer and the substrate for connection.

9. The semiconductor power device of claim 8, wherein the metal bonds are formed by a metal eutectic method or a metal sintering method.

10. The semiconductor power device of claim 9, wherein a material of the metal eutectic method is selected from the group consisting of gold, gold/tin, tin/silver/bismuth, tin/silver/bismuth/copper and tin/silver/copper, and a material of the metal sintering method is selected from the group consisting of silver metal particles, copper metal particles and silver-indium alloy particles.

11. The semiconductor power device of claim 1, wherein the ceramic-metal composite circuit substrate further comprises a plurality of metal leads, which are disposed on the first side of the ceramic insulating layer, and the plurality of metal leads are respectively electrically connected to the plurality of first electric-conducting metal pads.

12. The semiconductor power device of claim 11, wherein the ceramic-metal composite circuit substrate further comprises a plurality of second electric-conducting metal pads, which are disposed on the second side of the ceramic insulating layer, and the plurality of second electric-conducting metal pads are respectively electrically connected to the plurality of first electric-conducting metal pads.

13. The semiconductor power device of claim 1, wherein the semiconductor power device is a transistor, and the plurality of electric-conducting pads comprise at least one gate electrode, at least one drain electrode and at least one source electrode.

14. The semiconductor power device of claim 1, wherein the semiconductor power device is a diode, and the plurality of electric-conducting pads comprise at least one drain electrode and at least one source electrode.

15. The semiconductor power device of claim 1, further comprising a vertical transistor, disposed on the ceramic-metal composite circuit substrate, and arranged on the first side and electrically connected to the flip chip, wherein the vertical transistor comprises a gate electrode, a drain electrode and a source electrode, the vertical transistor has a first surface away from the ceramic-metal composite circuit substrate and a second surface adjacent to the ceramic-metal composite circuit substrate, the gate electrode and the source electrode are arranged on the first surface and the drain electrode is arranged on the second surface, or the drain electrode is arranged on the first surface and the gate electrode and the source electrode are arranged on the second surface.

16. The semiconductor power device of claim 1, wherein a material of the flip chip is selected from the group consisting of gallium nitride, indium gallium nitride, aluminum gallium nitride, and indium aluminum gallium nitride.

17. The semiconductor power device of claim 1, wherein the ceramic-metal composite circuit substrate has a ceramic material and a metal material, the ceramic material is selected from the group consisting of aluminum oxide, aluminum nitride and silicon nitride, and the metal material is selected from the group consisting of copper, aluminum, silver and gold.

18. A semiconductor module, comprising:
a semiconductor power device, comprising:
a ceramic-metal composite circuit substrate, comprising:
a ceramic insulating layer, having a first side and a second side opposite to the first side;
a plurality of first electric-conducting metal pads, disposed on the first side of the ceramic insulating layer;
at least one first thermal-conducting metal pad, which is disposed on the first side of the ceramic insulating layer, and not electrically connected to each of the plurality of first electric-conducting metal pads;
at least one second thermal-conducting metal pad, which is disposed on the second side of the ceramic insulating layer; and
a plurality of metal leads, which are disposed on the first side of the ceramic insulating layer, and the plurality of metal leads are respectively electrically connected to the plurality of first electric-conducting metal pads;
a plurality of semiconductor devices, comprising:
at least one flip chip, disposed on the ceramic-metal composite circuit substrate, and arranged at the first side, wherein the at least one flip chip comprises:
a substrate;
a semiconductor structural layer, disposed on the substrate;
a plurality of electric-conducting pads, disposed on the semiconductor structural layer, and electrically connected to the semiconductor structural layer and the plurality of first electric-conducting metal pads, wherein the semiconductor structural layer is arranged between the substrate and the plurality of electric-conducting pads; and
at least one floating thermal-conducting metal pad, disposed on the semiconductor structural layer, and connected to the at least one first thermal-conducting metal pad, wherein the semiconductor structural layer is arranged between the substrate and the at least one floating thermal-conducting metal pad, and the at least one floating thermal-conducting metal pad is not electrically connected to the plurality of electric-conducting pads and the semiconductor structural layer;
a metal thermal-conducting layer, disposed on the substrate; and
a driving circuit substrate, electrically connected to the plurality of metal leads, the plurality of first electric-conducting metal pads or the plurality of electric-conducting pads.
